(19) United States
(12) Patent Application Publication
(10) Pub. No.: US 2023/0290840 A1
(43) Pub. Date: Sep. 14, 2023

(54) BACK SIDE POWER SUPPLY INTERCONNECT ROUTING

(71) Applicant: Taiwan Semiconductor Manufacturing Co., Ltd., Hsinchu (TW)

(72) Inventors: Nail Etkin Can AKKAYA, San Jose, CA (US); Mahmut SINANGIL, Campbell, CA (US); Yih WANG, Hsinchu City (TW); Jonathan Tsung-Yung CHANG, Hsinchu City (TW)

(73) Assignee: Taiwan Semiconductor Manufacturing Co., Ltd., Hsinchu (TW)

(21) Appl. No.: 17/661,386

(22) Filed: Apr. 29, 2022

Related U.S. Application Data
(60) Provisional application No. 63/319,080, filed on Mar. 11, 2022.

(51) Int. Cl. H01L 29/417; H01L 27/088; H01L 23/528

(52) U.S. Cl. CPC H01L 29/41766; H01L 27/088; H01L 23/528

(57) ABSTRACT

The present disclosure describes a structure with front and back side power supply interconnects. The structure includes a transistor structure disposed in a substrate, where the transistor structure includes a source/drain (S/D) region. The structure also includes a front side power supply line above a top surface of the substrate, wherein the front side power supply line is electrically connected to a power supply metal line. The structure further includes a back side power supply line below a bottom surface of the substrate. A front side metal via electrically connects the front side power supply line to a front surface of the S/D region. A back side metal via electrically connects the back side power supply line to a back surface of the S/D region.

### CROSS-REFERENCE TO RELATED APPLICATION

This application claims the benefit of U.S. Provisional Patent Application No. 63/319,080, titled “Write Assist Scheme with Back-Side Metal,” which was filed on Mar. 11, 2022 and is incorporated herein by reference in its entirety.

### BACKGROUND

Static random access memory (SRAM) is a type of semiconductor memory used in computing applications that require, for example, high-speed data access. For example, cache memory applications use SRAM to store frequently-accessed data—e.g., data accessed by a central processing unit.

The SRAM's cell structure and architecture enable high-speed data access. The SRAM cell can include a bi-stable flip-flop structure with, for example, four to ten transistors. An SRAM architecture can include one or more arrays of memory cells and support circuitry. Each of the SRAM arrays is arranged in rows and columns called “wordlines” and “bitlines,” respectively. The support circuitry includes address and driver circuits to access each of the SRAM cells—through the wordlines and bitlines—for various SRAM operations.

### BRIEF DESCRIPTION OF THE DRAWINGS

Aspects of the present disclosure are best understood from the following detailed description when read with the accompanying figures. It is noted that, according to the standard practice in the industry, various features are not drawn to scale. In fact, the dimensions of the various features may be arbitrarily increased or reduced for clarity of discussion.

FIG. 1 is an illustration of a static random access memory (SRAM) device with a memory cell power supply, according to some embodiments of the present disclosure.

FIG. 2 is an illustration of an example SRAM circuit topology with a memory cell power supply, according to some embodiments of the present disclosure.

FIG. 3 is an illustration of a top-level power supply interconnect routing for a memory cell array, according to some embodiments of the present disclosure.

FIG. 4 is an illustration of a cross-sectional view of a power supply interconnect routing for memory cells, according to some embodiments of the present disclosure.

FIG. 5 is an illustration of another cross-sectional view of a power supply interconnect routing for memory cells, according to some embodiments of the present disclosure.

FIG. 6 is an illustration of yet another cross-sectional view of a power supply interconnect routing for memory cells, according to some embodiments of the present disclosure.

FIG. 7 is an illustration of a method for forming a power supply interconnect structure for a memory cell, according to some embodiments of the present disclosure.

FIG. 8 is an illustration of a cross-sectional view of a portion of an SRAM array formed in a substrate, according to some embodiments of the present disclosure.

FIG. 9 is an illustration of a cross-sectional view of a portion of an SRAM array with a front side interconnect structure, according to some embodiments of the present disclosure.

FIG. 10 is an illustration of a cross-sectional view of a portion of an SRAM array with front and back side interconnect structures, according to some embodiments of the present disclosure.

FIG. 11 is an illustration of an integrated circuit manufacturing system and associated integrated circuit manufacturing flow, according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are merely examples and are not intended to be limiting. In addition, the present disclosure repeats reference numerals and/or letters in the various examples. This repetition is for the purpose of simplicity and clarity and, unless indicated otherwise, does not in itself dictate a relationship between the various embodiments and/or configurations discussed.

The following disclosure describes aspects of an electronic device, such as a static random access memory (SRAM) device, with a power supply interconnect routing that increases resistance from a source of a power supply to a destination of the power supply. For example, the disclosure describes a power supply interconnect for memory cells that is routed above and below a substrate of memory cells in a memory device (e.g., memory cells in an SRAM array). With the power supply interconnect routed above and below the substrate, interconnect resistance from a source of the power supply to the memory cell can be increased, resulting in an increase in voltage drop at the memory cell—i.e., lower power supply voltage level at the memory cell. The lower power supply voltage level can improve the performance of write operations in memory cells since a transition time from a ‘0’ or a logic low value (e.g., ground or 0 V) to a ‘1’ or a logic high value (e.g., lower power supply voltage level at the memory cells)—and vice versa—will be shorter.

Though the description below is in the context of an SRAM device, the power supply interconnect routing embodiments described herein apply to other types of electronic devices, such as central processing units, graphic processing units, and application-specific integrated circuits.

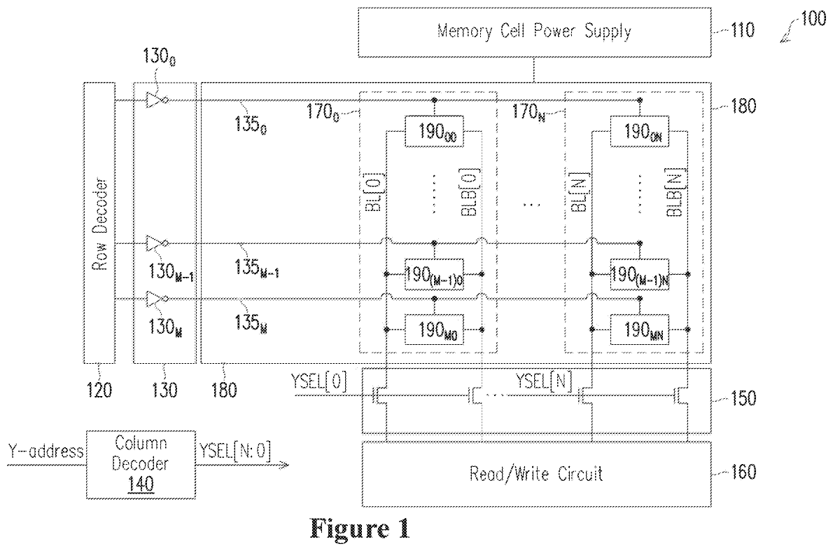

FIG. 1 is an illustration of an SRAM device 100 with a memory cell power supply 110, according to some embodiments of the present disclosure. SRAM device 100 includes a row decoder 120, a wordline driver 130, a column decoder 140, a column multiplexer (MUX) 150, a read/write circuit 160, and an SRAM array 180. SRAM array 180 includes columns of SRAM cells 170₀-170_{N}. SRAM device 100 can include other circuit elements and control circuits, which are not shown in FIG. 1.

Each of the SRAM cells in SRAM array 180 is accessed—e.g., for memory read and memory write operations—using a memory address. Based on the memory address, row decoder 120 selects a row of memory cells to access through a wordline driver output 135 of wordline driver 130. Also, based on the memory address, column decoder 140 selects a column of memory cells 170₀-170_{N} to access through column MUX 150. For a memory read operation, read/write circuit 160 senses a voltage level on bitline pairs BL/BLB. For a memory write operation, read/write circuit 160 generates voltages for bitline pairs BL/BLB in columns of memory cells 170₀-170_{N}. The notation “BL” refers to a bitline, and the notation “BLB” refers to the complement of BL. The intersection of the accessed row and the accessed column of memory cells results in access to a single memory cell 190.

Each of columns of memory cells 170₀-170_{N} includes memory cells 190. Memory cells 190 can be arranged in one or more arrays in SRAM device 100. In the present disclosure, a single SRAM array 180 is shown to simplify the description of the disclosed embodiments. SRAM array 180 has “M” number of rows and “N” number of columns. The notation “19000” refers to memory cell 190 located in row ‘0’, column 170₀. Similarly, the notation “190_{MN}” refers to memory cell 190 located in row ‘M’, column 170_{N}.

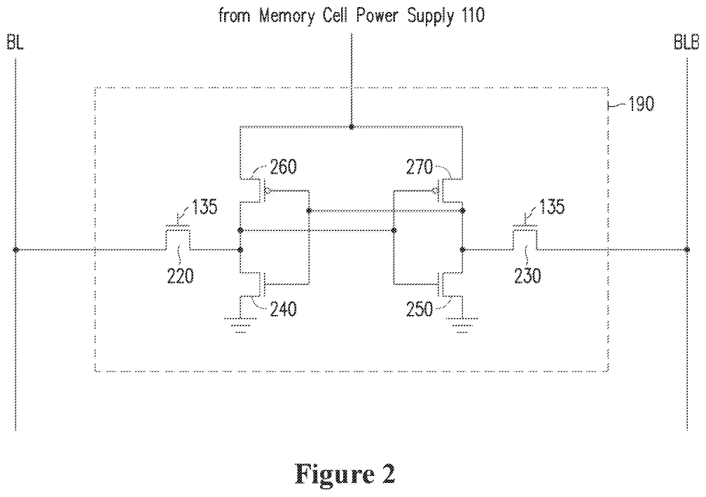

In some embodiments, memory cell 190 can have a six transistor (“6T”) circuit topology. FIG. 2 is an illustration of an example 6T circuit topology for memory cell 190 with memory cell power supply 115, according to some embodiments of the present disclosure. The 6T circuit topology includes n-type field effect transistor (NFET) pass devices 220 and 230, NFET pull down devices 240 and 250, and p-type FET (PFET) pull up devices 260 and 270. The FET devices (e.g., NFET devices and PFET devices) can be planar metal-oxide-semiconductor FETs, finFETs, gate-all-around FETs, any suitable FETs, or combinations thereof. Other memory cell topologies, such as four transistor (“4T”), eight transistor (“8T”), and ten transistor (“10T”) circuit topologies, are within the scope of the present disclosure.

Wordline driver output 135 controls NFET pass devices 220 and 230 to pass voltages from the bitline pair BL/BLB to a bi-stable flip-flop structure formed by NFET pull down devices 240 and 250 and PFET pull up devices 260 and 270. The bitline pair BL/BLB voltages can be used during a memory read operation and a memory write operation. During the memory read operation, the voltage applied by wordline driver output 135 to the gate terminals of NFET pass devices 220 and 230 can be at a sufficient voltage level, such as a logic high value (e.g., a power supply voltage, such as 1.0 V, 1.2 V, 1.8 V, 2.4 V, 3.3 V, 5 V, or any other suitable voltage), to pass voltages stored in the bi-stable flip-flop structure to the BL and BLB, which can be sensed by read/write circuit 160. For example, if a ‘1’ or logic high value (e.g., a power supply voltage, such as 1.0 V, 1.2 V, 1.8 V, 2.4 V, 3.3 V, 5 V, and any other suitable voltage) is passed to the BL and a ‘0’ or logic low value (e.g., ground or 0 V) is passed to the BLB, read/write circuit 160 can sense (or read) these values. During the memory write operation, if the BL is at a ‘1’ or a logic high value and the BLB is at a ‘0’ or a logic low value, the voltage applied by wordline driver 130 to the gate terminals of NFET pass devices 220 and 230 can be at a sufficient voltage level to pass the BL's logic high value and the BLB's logic low value to the bi-stable flip-flop structure. As a result, these logic values are written (or programmed) into the bi-stable flip-flop structure.

In some embodiments, memory cell power supply 110 provides a power supply to memory cells 190 in SRAM array 180. In some embodiments, SRAM device 100 can operate in a single power supply domain, where row decoder 120, wordline driver 130, column decoder 140, MUX 150, read/write circuit 160, and SRAM array 180 receive a nominal power supply voltage. The nominal power supply voltage is also referred to herein as “power supply VDD.” For example, power supply VDD can be 1.0 V, 1.2 V, 1.8 V, 2.4 V, 3.3 V, 5 V, or any other suitable voltage.

In some embodiments, SRAM device 100 can operate in multiple power supply domains, where row decoder 120, wordline driver 130, column decoder 140, MUX 150, and read/write circuit 160 are provided power supply VDD and SRAM array 180 is provided a lower power supply voltage. This lower power supply voltage is also referred to herein as “power supply VDDAI.” The voltage level of power supply VDDAI can be at a level as to not impact signal integrity, noise margins, or other performance factors of the memory write operation. For example, the voltage level of power supply VDDAI can be about 100 mV to about 200 mV lower than the voltage level of power supply VDD. With the lower voltage level of power supply VDDAI, the memory write operation of SRAM device 100 can be improved since the transition time from a ‘0’ or a logic low value (e.g., ground or 0 V) to a ‘1’ or a logic high value (e.g., power supply VDDAI)—and vice versa—will be shorter.

In some embodiments, through the power supply interconnect routing techniques described herein, the power supply voltage level received at memory cells 190 in SRAM array 180 can be lower than that of power supply VDD (for a single power supply domain SRAM device 100) or that of power supply VDDAI (for a multiple power supply domain SRAM device 100). In some embodiments, the interconnect routing from memory cell power supply 110 to memory cells 190 can be lengthened—thus increasing the interconnect resistance from memory cell power supply 110 to memory cells 190—by routing the power supply interconnect above and below a substrate of the memory cells. In turn, an increase in the voltage drop from memory cell power supply 110 to memory cells 190 can be achieved. With the lower voltage level of the power supply at memory cells 190, the memory write operation of SRAM device 100 can be further improved since the transition time from a ‘0’ or a logic low value (e.g., ground or 0 V) to a ‘1’ or a logic high value (e.g., lower power supply voltage level than that of power supply VDD or that of power supply VDDAI)—and vice versa—will be shorter.

A benefit, among others, of the power supply interconnect routing embodiments described herein is that additional circuits are not needed to achieve the same write-assist goals during memory write operations. These additional write-assist circuits can add complexity to SRAM device 100, which are not introduced by the disclosed power supply interconnect routing embodiments. These complexities include circuit timing considerations and power/circuit area overhead. Alternatively, in some embodiments, the power supply interconnect routing embodiments described herein can be implemented with the additional write-assist circuits based on the design of SRAM device 100.

Another benefit of the embodiments described herein is that a lower level interconnect routing area—e.g., interconnect routing area directly above the transistor level, such as at the metallization M0 level—can be increased. This is because the power supply interconnect embodiments described herein are routed above and below a substrate of the memory cells, thus relieving interconnect routing congestion above the transistor level.

Though the power supply interconnect routing embodiments below are described in the context of an SRAM device, these embodiments apply to other types of electronic circuits, such as central processing units, graphic processing units, and application-specific integrated circuits.

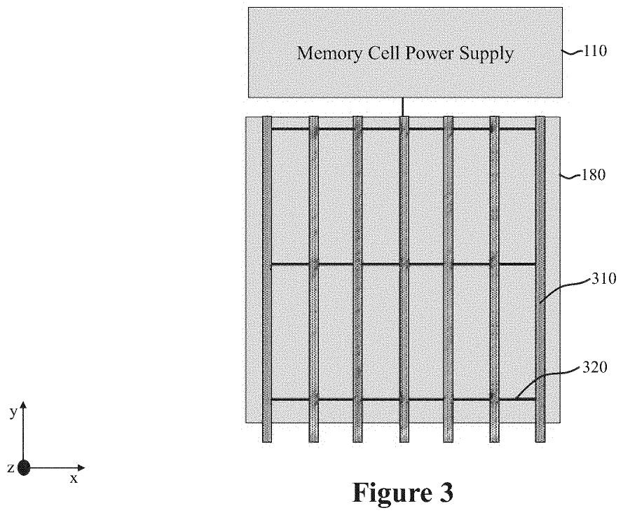

FIG. 3 is an illustration of a top-level power supply interconnect routing for SRAM array 180, according to some embodiments of the present disclosure. A power supply interconnect 310 can represent an interconnect structure routed in a first direction (e.g., along the y-axis)—e.g., at the metallization M2 level—and electrically coupled to memory cell power supply 110. In some embodiments, memory cell power supply 110 can provide power supply VDD or power supply VDDAI through a network of upper level interconnect structures—e.g., at the metallization M3 level and/or higher metallization levels—based on the design of SRAM device 100.

A power supply interconnect 320 can represent an interconnect structure routed in a second direction (e.g., along the x-axis) and below power supply interconnect 310—e.g., at the metallization M1 level. Power supply interconnect 320 is electrically connected to power supply interconnect 310 through metal vias (not shown in FIG. 3). Further, power supply interconnect 320 can be electrically connect to yet another interconnect structure routed in the first direction (e.g., along the y-axis) and below power supply interconnect 320—e.g., at the metallization M0 level. Power supply interconnect 320 is electrically connected to the lower level interconnect structure through metal vias (not shown in FIG. 3). The lower level interconnect structure is not shown in FIG. 3 because power supply interconnect 310 (e.g., also routed along the y-axis) overlaps it from the top-level view.

The lower level interconnect structure—below power supply interconnect 320—is electrically connected to memory cells 190 in SRAM array 180 through metal vias. In some embodiments, the metal vias are in contact with source/drain (S/D) regions of pull-up transistors in memory cells 190—e.g., S/D regions of PFET pull up devices 260 and 270 in FIG. 2. Further, as described below, the power supply interconnect routing for SRAM array 180 can include interconnect routing within and below a bottom surface of a substrate on which memory cells 190 in SRAM array 180 are formed on, according to some embodiments of the present disclosure. In turn, the power supply interconnect routing from memory cell power supply 110 to memory cells 190 can be lengthened, thus increasing the interconnect resistance from memory cell power supply 110 to memory cells 190. This increase in the interconnect resistance results in an increase in the voltage drop from memory cell power supply 110 to memory cells 190 and a lower power supply voltage level at memory cells 190. With the lower voltage level of the power supply at memory cells 190, the memory write operation of SRAM device 100 can be improved since the transition time from a ‘0’ or a logic low value (e.g., ground or 0 V) to a ‘1’ or a logic high value (e.g., lower power supply voltage level at memory cells 190)—and vice versa—will be shorter.

The interconnect structures described above are exemplary. Interconnect structures at other metallization levels can be used to implement the routing of power supply VDD or power supply VDDAI from memory cell power supply 110 to memory cells 190 in SRAM array 180.

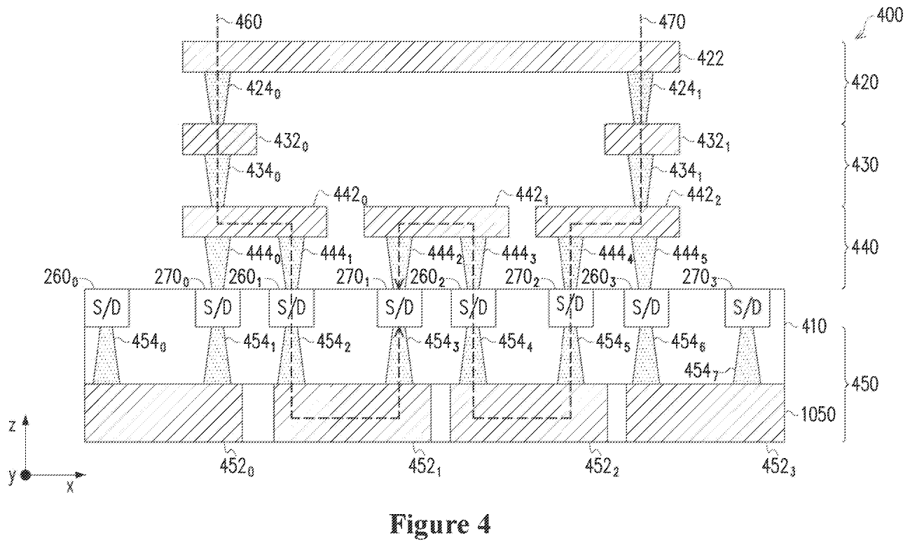

FIG. 4 is an illustration of a cross-sectional view 400 of a power supply interconnect routing for memory cells 190, according to some embodiments of the present disclosure. Cross-sectional view 400 includes a depiction of S/D regions of eight PFET pull up devices—PFET pull up devices 260₀-260₃ and 270₀-270₃—which correspond to PFET pull up devices in four memory cells 190 of SRAM array 180. As shown in FIG. 4, the S/D regions of PFET pull up devices 260₀-260₃ and 270₀-270₃ can be disposed in a substrate 410. The front surfaces of the S/D regions of PFET pull up devices 260₀-260₃ and 270₀-270₃ are coplanar with a top surface of the substrate (e.g., along the x-axis), according to some embodiments of the present disclosure.

Cross-sectional view 400 includes front side interconnect structures 420, 430, and 440 above a top surface of substrate 410 and a back side interconnect structure 450 within and below a bottom surface of substrate 410 (opposite to the top surface of substrate 410), according to some embodiments of the present disclosure. Front side interconnect structures 420, 430, and 440 can be at the metallization M2, M1, and M0 levels, respectively, according to some embodiments of the present disclosure. Front side interconnect structure 420 includes a front side metal line 422 and front side metal vias 424₀ and 424₁. In some embodiments, memory cell power supply 110 can provide power supply VDD or power supply VDDAI through a network of upper level front side interconnect structures—e.g., at the metallization M3 level and/or higher metallization levels—to front side interconnect structure 420.

Front side interconnect structure 430 includes front side metal lines 432₀ and 432₁ and front side metal vias 434₀ and 434₁. Front side metal lines 432₀ and 432₁ are electrically connected to front side metal line 422 through front side metal vias 424₀ and 424₁, respectively, which are in contact with front side metal lines 422, 432₀, and 432₁. Front side interconnect structure 440 includes front side metal lines 442₀-442₃ and front side metal vias 444₀-444₅. Front side metal lines 442₀ and 442₂ are electrically connected to front side metal lines 432₀ and 432₁ through front side metal vias 434₀ and 434₁, respectively, which are in contact with front side metal lines 432₀, 432₁, 442₀, and 442₂. Further, front side metal lines 442₂-442₀ are electrically connected to the front surfaces of S/D regions of PFET pull up devices 260₁-260₃ and 270₀-270₂ through front side metal vias 444₀-444₅, which are in contact with front side metal lines 442₀-442₂ and the front surfaces of S/D regions of PFET pull up devices 260₁-260₃ and 270₀-270₂.

In some embodiments, the front surfaces of S/D regions of PFET pull up devices 260₀ and 270₃ are in contact with metal vias from a similar arrangement of interconnect structures as front side interconnect structures 420, 430, and 440. For example, the front surface of S/D region of PFET pull device 260₀ can be in contact with front side metal via 444₅ associated with a similar arrangement of interconnect structures as front side interconnect structures 420, 430, and 440. The front surface of S/D region of PFET pull up device 270₃ can be in contact with a front side metal via 444₀ associated with another similar arrangement of interconnect structures as front side interconnect structures 420, 430, and 440.

Referring to FIG. 4, cross-sectional view 400 includes a back side interconnect structure 450, which can be at the back side metallization BM0 level, according to some embodiments of the present disclosure. Back side interconnect structure 450 includes back side metal lines 452₀-452₃ and back side metal vias 454₀-454₇. Back side metal lines 452₀-452₃ are electrically connected to the back surfaces of S/D regions of PFET pull up devices 260₀-260₃ and 270₀-270₃ through back side metal vias 454₀-454₇, which are in contact with back side metal lines 452₀-452₃ and the back surfaces of S/D regions of PFET pull up devices 260₀-260₃ and 270₀-270₃. The back surfaces of S/D regions of PFET pull up devices 260₀-260₃ and 270₀-270₃ are opposite to the front surfaces of S/D regions of PFET pull up devices 260₀-260₃ and 270₀-270₃.

Dashed arrows represent a first current flow 460 and a second current flow 470 from front side metal line 422 in front side interconnect structure 420 to the S/D region of PFET pull up device 270₁. For first current flow 460, the current traverses through front side metal line 422, front side metal via 424₀, front side metal line 432₀, front side metal via 434₀, front side metal line 442₀, and front side metal via 444₁ to reach the front surface of the SID region of PFET pull up device 260₁. The current from first current flow 460 enters the front surface and exits the back surface of the S/D region of PFET pull up device 260₁ into back side interconnect structure 450. In back side interconnect structure 450, the current from first current flow 460 traverses through back side metal via 454₂, back side metal line 452₁, and back side metal via 454₃ to reach the back surface of the S/D region of PFET pull up device 270₁.

For second current flow 470, the current traverses through front side metal line 422, front side metal via 424₁, front side metal line 432₁, front side metal via 434₁, front side metal line 442₂, and front side metal via 444₄ to reach the front surface of the S/D region of PFET pull up device 270₂. The current from second current flow 470 enters the front surface and exits the back surface of the S/D region of PFET pull up device 270₂ into back side interconnect structure 450. In back side interconnect structure 450, the current from second current flow 470 traverses through back side metal via 454₅, back side metal line 452₂, and back side metal via 454₄ to reach the back surface of the S/D region of PFET pull up device 260₂. The current from second current flow 470 enters the back surface and exits the front surface of the S/D region of PFET pull up device 260₂ into front side interconnect structure 440. In front side interconnect structure 440, the current from second current flow 470 traverses front side metal via 444₃, front side metal line 442₁, and front side metal via 444₂ to reach the front surface of the S/D region of PFET pull up device 270₁.

With back side interconnect structure 450, the paths for first current flow 460 and second current flow 470 can be lengthened, as compared to routing with only front side interconnect structures 420, 430, and 440. The lengthened current paths for first current flow 460 and second current flow 470 increase the interconnect resistance from memory cell power supply 110 to memory cells 190. In turn, an increase in the voltage drop from memory cell power supply 110 to memory cells 190 can be achieved. With the lower voltage level of the power supply at memory cells 190, the memory write operation of SRAM device 100 can be improved since the transition time from a ‘0’ or a logic low value (e.g., ground or 0 V) to a ‘1’ or a logic high value (e.g., lower power supply voltage level at memory cells 190)—and vice versa—will be shorter.

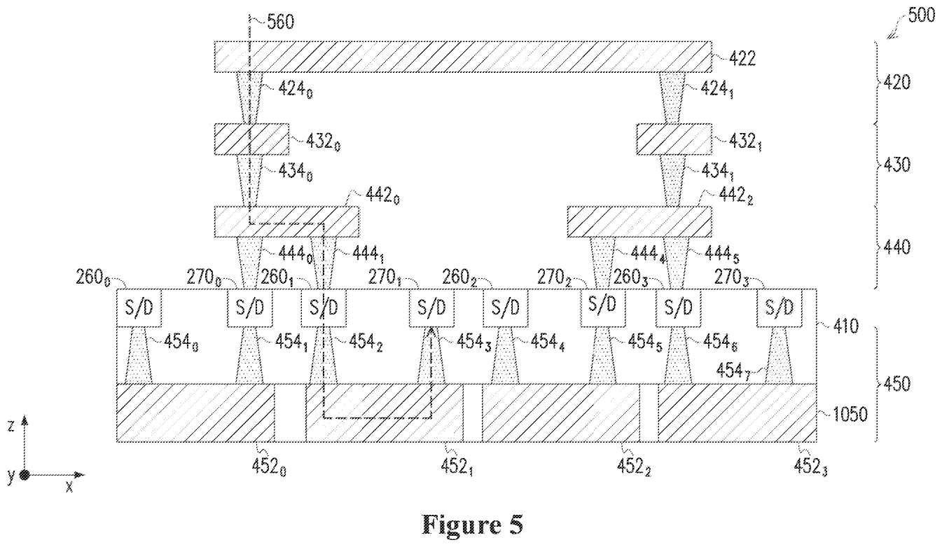

FIG. 5 is an illustration of another cross-sectional view 500 of a power supply interconnect routing for memory cells 190, according to some embodiments of the present disclosure. Compared to cross-sectional view 400 of FIG. 4, cross-sectional view 500 of FIG. 5 does not include front side metal line 442₁ and front side metal vias 444₂ and 444₃ in front side interconnect structure 440. As a result of the different interconnect structure in cross-sectional view 500, current flows in a single path—a current flow 560—from front side metal line 422 in front side interconnect structure 420 to the S/D region of PFET pull up device 270₁.

For current flow 560, the current traverses through front side metal line 422, front side metal via 424₀, front side metal line 432₀, front side metal via 434₀, front side metal line 442₀, and front side metal via 444₁ to reach the front surface of the S/D region of PFET pull up device 260₁. The current from current flow 560 enters the front surface and exits the back surface of the S/D region of PFET pull up device 260₁ into back side interconnect structure 450. In back side interconnect structure 450, the current from current flow 560 traverses through back side metal via 454₂, back side metal line 452₁, and back side metal via 454₃ to reach the back surface of the S/D region of PFET pull up device 270₁.

In some embodiments, since the current path for cross-sectional view 500 is different from that of cross-sectional view 400 of FIG. 4, the interconnect resistance from memory cell power supply 110 to memory cells 190 can be different. For example, the interconnect resistance associated with current flow 560 of FIG. 5 can be higher than the interconnect resistance associated with first current flow 460 and second current flow 470 of FIG. 4. As a result of the higher interconnect resistance associated with current flow 560, a greater increase in the voltage drop from memory cell power supply 110 to memory cells 190 can be achieved, according to some embodiments of the present disclosure. The greater voltage drop can result in a lower voltage level of the power supply at memory cells 190, as compared to power supply interconnect routing in cross-sectional view 400 of FIG. 4.

Conversely, the interconnect resistance associated with current flow 560 of FIG. 5 can be lower than the interconnect resistance associated with first current flow 460 and second current flow 470 of FIG. 4. As a result of the lower interconnect resistance associated with current flow 560, a lower increase in the voltage drop from memory cell power supply 110 to memory cells 190 can be achieved, according to some embodiments of the present disclosure. The lower voltage drop can result in a higher voltage level of the power supply at memory cells 190, as compared to power supply interconnect routing in cross-sectional view 400 of FIG. 4.

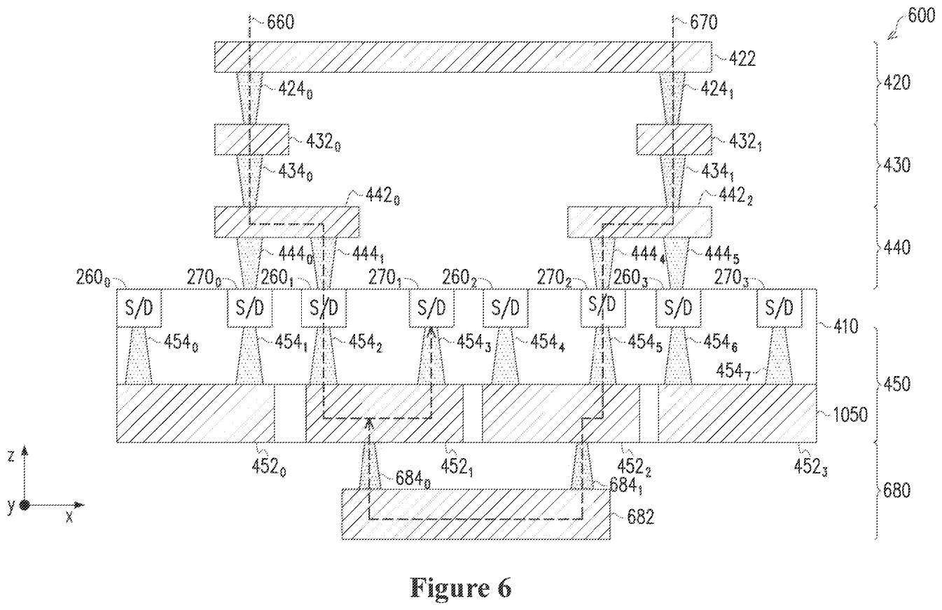

FIG. 6 is an illustration of yet another cross-sectional view 600 of a power supply interconnect routing for memory cells 190, according to some embodiments of the present disclosure. Compared to cross-sectional view 500 of FIG. 5, cross-sectional view 600 of FIG. 6 includes another back side interconnect structure 680—e.g., at the back side metallization BM1 level—according to some embodiments of the present disclosure. Back side interconnect structure 480 includes back side metal line 682 and back side metal vias 684₀ and 684₁. As a result of the different interconnect structure in cross-sectional view 600, current can flow in two different paths—a first current flow 660 and a second current flow 670—from front side metal line 422 in front side interconnect structure 420 to the S/D region of PFET pull up device 270₁.

For first current flow 660, the current traverses through front side metal line 422, front side metal via 424₀, front side metal line 432₀, front side metal via 434₀, front side metal line 442₀, and front side metal via 444₁ to reach the front surface of the S/D region of PFET pull up device 260₁. The current from first current flow 660 enters the front surface and exits the back surface of the S/D region of PFET pull up device 260₁ into back side interconnect structure 450. In back side interconnect structure 450, the current from first current flow 660 traverses through back side metal via 454₂, back side metal line 452₁, and back side metal via 454₃ to reach the back surface of the S/D region of PFET pull up device 270₁.

For second current flow 670, the current traverses through front side metal line 422, front side metal via 424₁, front side metal line 432₁, front side metal via 434₁, front side metal line 442₂, and front side metal via 444₄ to reach the front surface of the S/D region of PFET pull up device 270₂. The current from second current flow 670 enters the front surface and exits the back surface of the S/D region of PFET pull up device 270₂ into back side interconnect structure 450. In back side interconnect structure 450, the current from second current flow 670 traverses through back side metal via 454₅ and back side metal line 452₂ to reach back side interconnect structure 680. In back side interconnect structure 680, the current from second current flow 670 traverses through back side metal via 684₁, back side metal line 682, and back side metal via 684₀ to reach back side interconnect structure 450. In back side interconnect structure 450, the current from second current flow 670 traverses through back side metal line 452₁ and back side metal via 454₃ to reach the back surface of the S/D region of PFET pull up device 270₁.

In some embodiments, since the current paths for cross-sectional view 600 is different from that of cross-sectional view 400 of FIG. 4 and cross-sectional view 500 of FIG. 5, the interconnect resistance from memory cell power supply 110 to memory cells 190 can be different. For example, the interconnect resistance associated with first current flow 660 and second current flow 670 of FIG. 6 can be lower than the interconnect resistance associated with first current flow 460 and second current flow 470 of FIG. 4 and/or the interconnect resistance associated with current flow 560 of FIG. 5. As a result of the lower interconnect resistance associated with first current flow 660 and second current flow 670, a lower increase in the voltage drop from memory cell power supply 110 to memory cells 190 can be achieved, according to some embodiments of the present disclosure. The lower voltage drop can result in a higher voltage level of the power supply at memory cells 190, as compared to power supply interconnect routings in cross-sectional view 400 of FIG. 4 and cross-sectional view 500 of FIG. 5.

Conversely, the interconnect resistance associated with first current flow 660 and second current flow 670 of FIG. 6 can be higher than the interconnect resistance associated with first current flow 460 and second current flow 470 of FIG. 4 and/or the interconnect resistance associated with current flow 560 of FIG. 5. As a result of the higher interconnect resistance associated with first current flow 660 and second current flow 670, a greater increase in the voltage drop from memory cell power supply 110 to memory cells 190 can be achieved, according to some embodiments of the present disclosure. The greater voltage drop can result in a lower voltage level of the power supply at memory cells 190, as compared to power supply interconnect routings in cross-sectional view 400 of FIG. 4 and cross-sectional view 500 of FIG. 5.

The power supply interconnect routings in cross-sectional view 400 of FIG. 4, cross-sectional view 500 of FIG. 5, and cross-sectional view 600 of FIG. 6 are exemplary and show that the incorporation of power supply interconnect routing below the substrate can be used to achieve different interconnect resistances from memory cell power supply 110 to memory cells 190. As a result, different voltage levels of the power supply at memory cells 190 can be achieved. Based on a desired interconnect routing design of SRAM device 100 and a desired voltage level of the power supply at memory cells 190, the number of metallization levels above and below the substrate (e.g., the number of front side and back side interconnect structures) and the arrangement of the number of metal lines and metal vias in each metallization layer can vary.

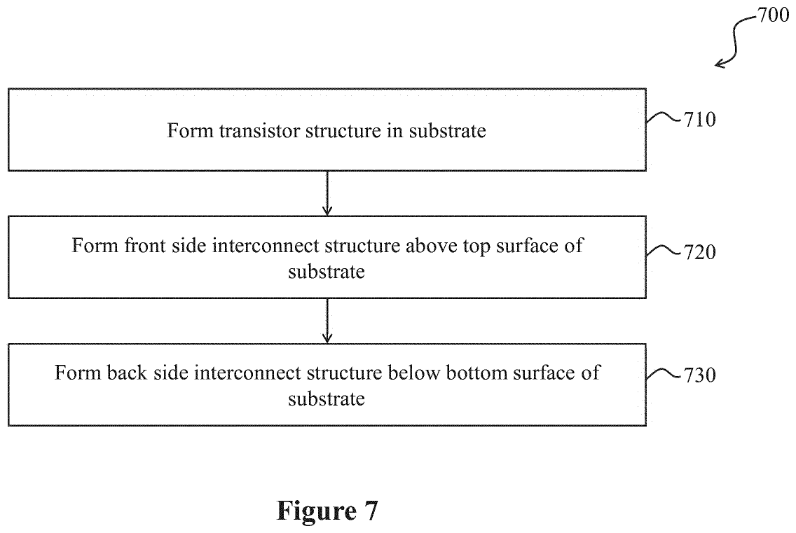

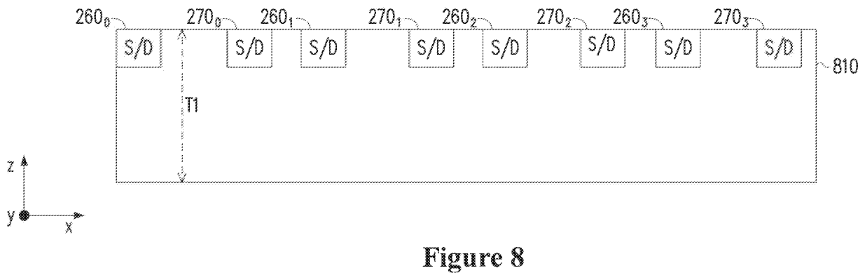

FIG. 7 is an illustration of a method 700 for forming a power supply interconnect structure for a memory cell, according to some embodiments of the present disclosure. For illustrative purposes, the operations of method 700 will be described with reference to FIGS. 8-10 and with reference to cross-sectional view 400 of FIG. 4. The operations of method 700 are also applicable to other power supply interconnect routings, such as those shown in cross-sectional view 500 of FIG. 5 and cross-sectional view 600 of FIG. 6. Some of the operations of method 700 can be performed simultaneously or in a different order. It should be noted that method 700 may not produce a complete device. Accordingly, it is understood that additional operations can be provided before, during, and after method 700, and that some other operations may only be briefly described herein.

In operation 710, a transistor structure is formed in a substrate, where the transistor structure includes a source/drain (S/D) region. FIG. 8 is an illustration of a cross-sectional view 800 of a portion of SRAM array 180 formed in a substrate 810, according to some embodiments of the present disclosure. Cross-sectional view 800 includes a depiction of S/D regions of eight PFET pull up devices—PFET pull up devices 260₀-260₃ and 270₀-270₃—which correspond to PFET pull up devices in four memory cells 190 of SRAM array 180. PFET pull up devices 260₀-260₃ and 270₀-270₃ can be planar metal-oxide-semiconductor FETs, finFETs, gate-all-around FETs, any suitable FETs, or combinations thereof.

In some embodiments, substrate 810 can include a semiconductor material, such as silicon (Si). In some embodiments, substrate 810 can include a silicon-on-insulator (SOI) substrate (e.g., SOI wafer). In some embodiments, substrate 410 can include (i) an elementary semiconductor, such as germanium (Ge); (ii) a compound semiconductor including silicon carbide (SiC), silicon arsenide (SiAs), gallium arsenide (GaAs), gallium phosphide (GaP), indium phosphide (InP), indium arsenide (InAs), indium antimonide (InSb), and/or a III-V semiconductor material; (iii) an alloy semiconductor including silicon germanium (SiGe), silicon germanium carbide (SiGeC), germanium stannum (GeSn), silicon germanium stannum (SiGeSn), gallium arsenic phosphide (GaAsP), gallium indium phosphide (GaInP), gallium indium arsenide (GaInAs), gallium indium arsenic phosphide (GaInAsP), aluminum indium arsenide (AlInAs), and/or aluminum gallium arsenide (AlGaAs); (iv) a silicon germanium (SiGe)-on insulator structure (SiGeOI); (v) germanium-on-insulator (GeOI) structure; or (vi) a combination thereof. Further, substrate 410 can be doped depending on design requirements (e.g., p-type substrate or n-type substrate). In some embodiments, substrate 410 can be doped with p-type dopants (e.g., boron, indium, aluminum, or gallium) or n-type dopants (e.g., phosphorus or arsenic).

In some embodiments, substrate 810 can have a thickness between about 20 nm and about 500 nm. Below this range of thickness, substrate 810 may not be thick enough to form the elements of SRAM device 100 (e.g., PFET pull up devices 260₀-260₃ and 270₀-270₃). On the other hand, if substrate 810 is thicker than 500 nm, the time and cost of fabricating the elements of SRAM array 180 through a bottom surface of substrate 810 (e.g., back side interconnect structure 450 of FIG. 4) increases.

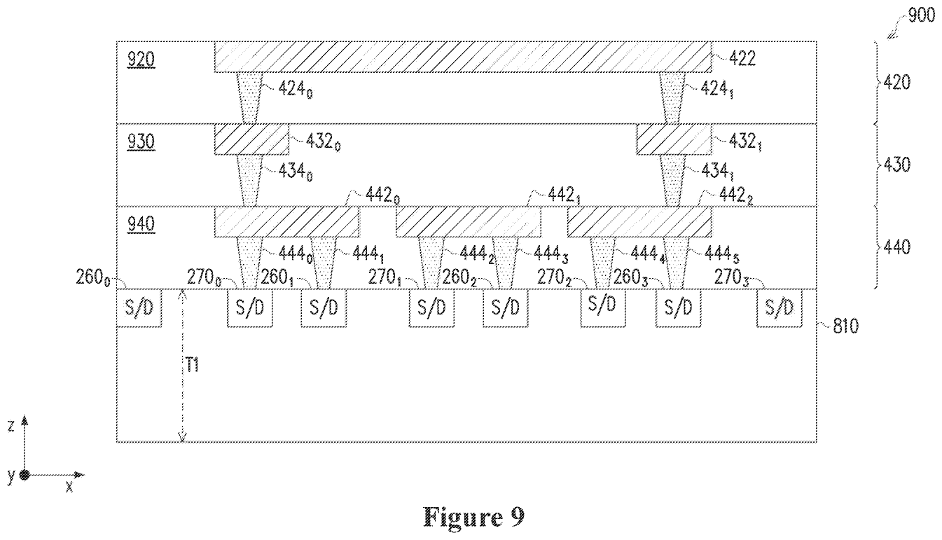

In operation 720, a front side interconnect structure is formed above a top surface of the substrate. FIG. 9 is an illustration of a cross-sectional view 900 of a portion of SRAM array 180 with a front side interconnect structure, according to some embodiments of the present disclosure. Cross-sectional view 900 includes front side interconnect structures 420, 430, and 440, which can be at the metallization M2, M1, and M0 levels, respectively, according to some embodiments of the present disclosure. In some embodiments, memory cell power supply 110 can provide power supply VDD or power supply VDDAI through a network of upper level front side interconnect structures—e.g., at the metallization M3 level and/or higher metallization levels—to front side interconnect structure 420.

Front side interconnect structures 420, 430, and 440 can be formed in a sequential manner, according to some embodiments of the present disclosure. First, referring to FIG. 9, front side interconnect structure 440 (e.g., at the metallization M0 level) is formed above the top surface of substrate 810. For example, an interlayer dielectric (ILD) layer 940 is formed above the top surface of substrate 810 (e.g., directly above the S/D regions of PFET pull up devices 260₃-260₀ and 270₃-270₀). ILD layer 940 can include an insulating material, such as silicon oxide, silicon nitride (SiN), silicon carbon nitride (SiCN), silicon oxycarbon nitride (SiOCN), and silicon germanium oxide. After the formation of ILD layer 940, front side metal lines 442₀-442₂ and front side metal vias 444₀-444₅ are formed by a single damascene process or a dual damascene process. In some embodiments, front side metal lines 442₀-442₂ and front side metal vias 444₀-444₅ can include conductive materials, such as copper (Cu), a Cu alloy (e.g., a copper-ruthenium alloy, a copper-aluminum alloy, or a copper-manganese alloy), and any other suitable metal or alloy.

Second, referring to FIG. 9, front side interconnect structure 430 (e.g., at the metallization M1 level) is formed above front side interconnect structure 440. For example, an ILD layer 930 is formed above front side interconnect structure 440. ILD layer 930 can include an insulating material, such as those discussed above with regard to ILD layer 940 in front side interconnect structure 440. After the formation of ILD layer 930, front side metal lines 432₀ and 432₁ and front side metal vias 434₀ and 434₁ are formed by a single damascene process or a dual damascene process. In some embodiments, front side metal lines 432₀ and 432₁ and front side metal vias 434₀ and 434₁ can include conductive materials, such as those discussed above with regard to front side metal lines 442₀-442₂ and front side metal vias 444₀-444₅ in front side interconnect structure 440.

Third, referring to FIG. 9, front side interconnect structure 420 (e.g., at the metallization M2 level) is formed above front side interconnect structure 430. For example, an ILD layer 920 is formed above front side interconnect structure 430. ILD layer 920 can include an insulating material, such as those discussed above with regard to ILD layer 940 in front side interconnect structure 440. After the formation of ILD layer 920, front side metal line 422 and front side metal vias 424₀ and 424₁ are formed by a single damascene process or a dual damascene process. In some embodiments, front side metal line 422 and front side metal vias 424₀ and 424₁ can include conductive materials, such as those discussed above with regard to front side metal lines 442₀-442₂ and front side metal vias 444₀-444₅ in front side interconnect structure 440.

Other processes can be used to form the front side interconnect structure shown in cross-sectional view 900—which can include front side interconnect structures 420, 430, and 440—and are within the scope of the present disclosure. Further, the number of metallization levels shown in in cross-sectional view 900 is not limiting and can vary based on a desired interconnect routing design of SRAM device 100 and a desired voltage level of the power supply at memory cells 190.

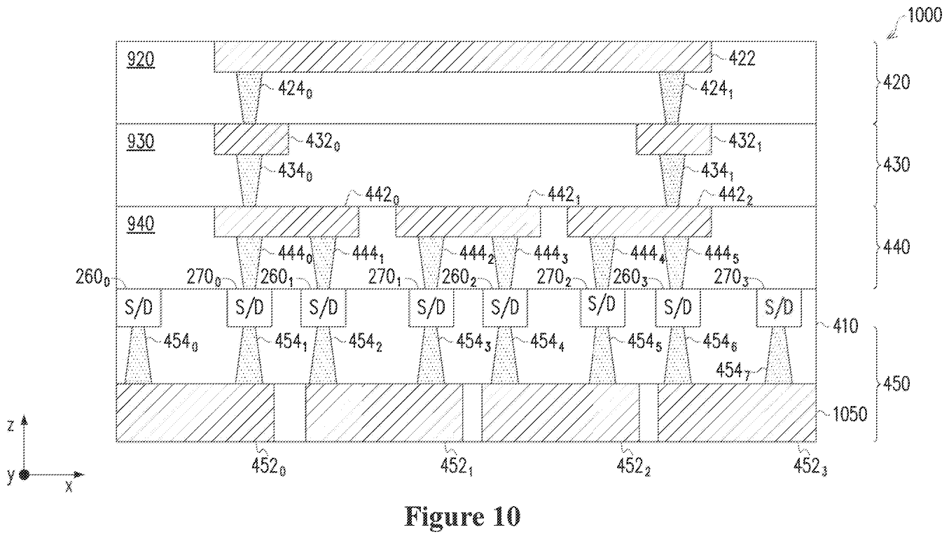

In operation 730, a back side interconnect structure is formed below the bottom surface of the substrate. FIG. 10 is an illustration of a cross-sectional view 1000 of a portion of SRAM array 180 with front and back side interconnect structures, according to some embodiments of the present disclosure. Cross-sectional view 1000 includes back side interconnect structure 450, which can be at the back side metallization BM0 level, according to some embodiments of the present disclosure.

Referring to FIG. 10, prior to forming back side interconnect structure 450, substrate 810 from FIG. 9 is thinned to form substrate 410 with a thickness T2 of about 20 nm to about 500 nm, according to some embodiments of the present disclosure. The thinning down process can include sequential operations of (i) performing a mechanical grinding process on the bottom surface of substrate 810 to thin down the substrate to a thickness of about 20 μm to about 26 μm, (ii) performing a dry etching process on the thinned substrate to further thin it down to a thickness of about 2 μm to about 5 μm, and (iii) performing a chemical mechanical polishing (CMP) process on thinned substrate to further thin it down to a thickness of about 20 nm to about 500 nm, thus forming substrate 410.

After the substrate thinning process, back side interconnect structure 450 is formed on the bottom surface of substrate 410, as shown in FIG. 10. For example, an ILD layer 1050 is formed below the bottom surface of substrate 410. ILD layer 1050 can include an insulating material, such as silicon oxide, SiN, SiCN, SiOCN, and silicon germanium oxide. After the formation of ILD layer 1050, back side metal lines 452₀-452₃ and back side metal vias 454₀-454₇ are formed by a single damascene process or a dual damascene process. In some embodiments, back side metal vias 454₀-454₇ are formed within (or embedded) in substrate 410, in which back side metal vias 454₀-454₇ are in contact with back side metal lines 452₀-452₃ along a surface of back side metal lines 452₀-452₃ coplanar with the bottom surface of substrate 410. In some embodiments, back side metal lines 452₀-452₃ and back side metal vias 454₀-454₇ can include conductive materials, such as Cu, a Cu alloy (e.g., a copper-ruthenium alloy, a copper-aluminum alloy, or a copper-manganese alloy), and any other suitable metal or alloy.

Other processes can be used to form the back side interconnect structure shown in cross-sectional view 1000—which can include back side interconnect structure 450—and are within the scope of the present disclosure. Further, the number of metallization levels shown in in cross-sectional view 1000 is not limiting and can vary based on a desired interconnect routing design of SRAM device 100 and a desired voltage level of the power supply at memory cells 190.

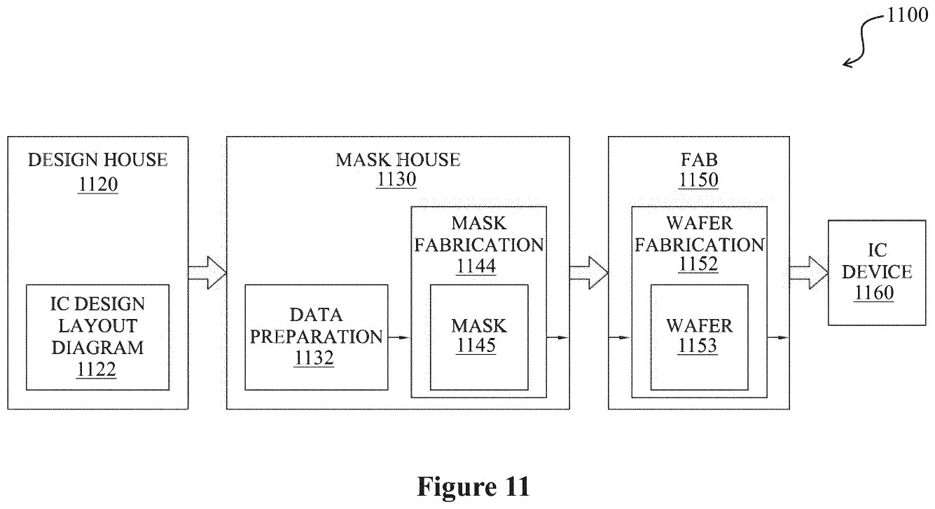

FIG. 11 is an illustration of an integrated circuit (IC) manufacturing system 1100 and associated integrated circuit manufacturing flow, according to some embodiments of the present disclosure. In some embodiments, based on a layout diagram, at least one of one or more semiconductor masks or at least one component in a layer of a semiconductor integrated circuit (e.g., SRAM device 100 of FIG. 1) is fabricated using IC manufacturing system 1100.

In FIG. 1, IC manufacturing system 1100 includes entities, such as a design house 1120, a mask house 1130, and an IC manufacturer/fabricator (“fab”) 1150, that interact with one another in the design, development, and manufacturing cycles and/or services related to manufacturing an IC device 1160 (e.g., SRAM device 100 of FIG. 1). The entities in IC manufacturing system 1100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1120, mask house 1130, and IC fab 1150 is owned by a single entity. In some embodiments, two or more of design house 1120, mask house 1130, and IC fab 1150 coexist in a common facility and use common resources.

Design house (or design team) 1120 generates an IC design layout diagram 1122. IC design layout diagram 1122 includes various geometrical patterns—for example, an IC layout associated with cross-sectional view 400 of FIG. 4, cross-sectional view 500 of FIG. 5, and cross-sectional view 600 of FIG. 6—designed for an IC device 1160—such as SRAM device 100 of FIG. 1. The geometrical patterns correspond to patterns of metal, oxide, or semiconductor layers that make up the various components of IC device 1160 to be fabricated. The various layers combine to form various IC features. For example, a portion of IC design layout diagram 1122 includes various IC features, such as an active region, gate electrode, source and drain, conductive segments or vias of an interlayer interconnection, to be formed in a semiconductor substrate (such as a silicon wafer) and various material layers disposed on the semiconductor substrate. Design house 1120 implements a proper design procedure to form IC design layout diagram 1122. The design procedure includes one or more of logic design, physical design or place and route. IC design layout diagram 1122 is presented in one or more data files having information of the geometrical patterns. For example, IC design layout diagram 1122 can be expressed in a GDSII file format or DFII file format.

Mask house 1130 includes data preparation 1132 and mask fabrication 1144. Mask house 1130 uses IC design layout diagram 1122 to manufacture one or more masks 1145 to be used for fabricating the various layers of IC device 1160 according to IC design layout diagram 1122. Mask house 1130 performs mask data preparation 1132, where IC design layout diagram 1122 is translated into a representative data file (“RDF”). Mask data preparation 1132 provides the RDF to mask fabrication 1144. Mask fabrication 1144 includes a mask writer. The mask writer converts the RDF to an image on a substrate, such as a mask (reticle) 1145 or a semiconductor wafer 1153. The IC design layout diagram 1122 is manipulated by mask data preparation 1132 to comply with particular characteristics of the mask writer and/or requirements of IC fab 1150. In FIG. 11, data preparation 1132 and mask fabrication 1144 are illustrated as separate elements. In some embodiments, data preparation 1132 and mask fabrication 1144 can be collectively referred to as “mask data preparation.”

In some embodiments, data preparation 1132 includes optical proximity correction (OPC) which uses lithography enhancement techniques to compensate for image errors, such as those that can arise from diffraction, interference, and other process effects. OPC adjusts IC design layout diagram 1122. In some embodiments, data preparation 1132 includes further resolution enhancement techniques (RET), such as off-axis illumination, sub-resolution assist features, phase-shifting masks, other suitable techniques, or combinations thereof. In some embodiments, inverse lithography technology (ILT) can also be used, which treats OPC as an inverse imaging problem.

In some embodiments, data preparation 1132 includes a mask rule checker (MRC) that checks the IC design layout diagram 1122 that has undergone processes in OPC with a set of mask creation rules which contain certain geometric and/or connectivity restrictions to ensure sufficient margins and to account for variability in semiconductor manufacturing processes. In some embodiments, the MRC modifies the IC design layout diagram 1122 to compensate for limitations during mask fabrication 1144, which may undo part of the modifications performed by OPC in order to meet mask creation rules.

In some embodiments, data preparation 1132 includes lithography process checking (LPC) that simulates processing that will be implemented by IC fab 1150 to fabricate IC device 1160. LPC simulates this processing based on IC design layout diagram 1122 to create a simulated manufactured device, such as IC device 1160. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, or combinations thereof. In some embodiments, after a simulated manufactured device has been created by LPC, if the simulated device is not close enough in shape to satisfy design rules, OPC and/or MRC can be repeated to further refine IC design layout diagram 1122.

It should be understood that the above description of data preparation 1132 has been simplified for the purposes of clarity. In some embodiments, data preparation 1132 includes additional features, such as a logic operation (LOP) to modify the IC design layout diagram 1122 according to manufacturing rules. Additionally, the processes applied to IC design layout diagram 1122 during data preparation 1132 can be executed in a variety of different orders.

After data preparation 1132 and during mask fabrication 1144, a mask 1145 or a group of masks 1145 are fabricated based on the modified IC design layout diagram 1122. In some embodiments, mask fabrication 1144 includes performing one or more lithographic exposures based on IC design layout diagram 1122. In some embodiments, an electron-beam (e-beam) or a mechanism of multiple e-beams is used to form a pattern on a mask (photomask or reticle) 1145 based on the modified IC design layout diagram 1122. Mask 1145 can be formed in various technologies. In some embodiments, mask 1145 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1145 includes a transparent substrate (e.g., fused quartz) and an opaque material (e.g., chromium) coated in the opaque regions of the binary mask. In another example, mask 1145 is formed using a phase shift technology. In a phase shift mask (PSM) version of mask 1145, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1144 is used in a variety of processes. For example, such a mask(s) is used in an ion implantation process to form various doped regions in semiconductor wafer 1153, in an etching process to form various etching regions in semiconductor wafer 1153, and/or in other suitable processes.

IC fab 1150 includes wafer fabrication 1152. IC fab 1150 is an IC fabrication business that includes one or more manufacturing facilities for the fabrication of a variety of different IC products. In some embodiments, IC fab 1150 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1150 uses mask(s) 1145 fabricated by mask house 1130 to fabricate IC device 1160. Thus, IC fab 1150 at least indirectly uses IC design layout diagram 1122 to fabricate IC device 1160. In some embodiments, semiconductor wafer 1153 is fabricated by IC fab 1150 using mask(s) 1145 to form IC device 1160. In some embodiments, the IC fabrication includes performing one or more lithographic exposures based at least indirectly on IC design layout diagram 1122. Semiconductor wafer 1153 includes a silicon substrate or other proper substrate having material layers formed thereon. Semiconductor wafer 1153 further includes one or more of various doped regions, dielectric features, and multilevel interconnect structures (formed at subsequent manufacturing steps).

Embodiments of the present disclosure describe a memory device, such as SRAM device 100 of FIG. 1, with a power supply interconnect routing that improves memory write operations. Specifically, the disclosure describes a power supply interconnect for memory cells that is routed above and below a substrate of the memory cells—such as the power supply interconnect routings shown in cross-sectional view 400 of FIG. 4, cross-sectional view 500 of FIG. 5, and cross-sectional view 600 of FIG. 6. With the power supply interconnect routed above and below the substrate, interconnect resistance from a source of the power supply (e.g., memory cell power supply 110 of FIG. 1) to the memory cell (e.g., memory cell 190 of FIG. 1) can be increased, resulting in an increase in voltage drop at the memory cell—i.e., lower power supply voltage level at the memory cell. The lower power supply voltage level can improve the performance of write operations in memory cells since the transition time from a ‘0’ or a logic low value (e.g., ground or 0 V) to a ‘1’ or a logic high value (e.g., lower power supply voltage level at the memory cells)—and vice versa—will be shorter.

Embodiments of the present disclosure include a semiconductor structure with a substrate, a first transistor structure, a second transistor structure, a first front side metal via, a second front side metal via, a first back side metal via, a second back side metal via, a front side metal line, and back side metal line. The first transistor structure is disposed in the substrate and includes a first source/drain (S/D) region. The second transistor structure is disposed in the substrate and includes a second S/D region. The first front side metal via is in contact with a front surface of the first S/D region, where the front surface of the first SID region is coplanar with a top surface of the substrate. The second front side metal via in contact with a front surface of the second S/D region, where the front surface of the second S/D region is coplanar with the top surface of the substrate. The first back side metal via is in contact with a back surface of the first S/D region, where the back surface of the first S/D region is opposite to the front surface of the first S/D region. The second back side metal via is in contact with a back surface of the second S/D region, where the back surface of the second S/D region is opposite to the front surface of the second S/D region. The front side metal line is above the top surface of the substrate and is in contact with the first and second front side metal vias. The back side metal line is below a bottom surface of the substrate and is in contact with the first back side metal via, where the bottom surface is opposite to the top surface of the substrate.

Embodiments of the present disclosure include a semiconductor structure with a transistor structure, a front side power supply line, a back side power supply line, a front side metal via, and a back side metal via. The transistor structure is disposed in a substrate and includes a source/drain (S/D) region. The front side power supply line is above a top surface of the substrate. The back side power supply line is below a bottom surface of the substrate, where the bottom surface is opposite to the top surface of the substrate. The front side metal via is electrically connected to a front surface of the S/D region and to the front side power supply line, where the front surface of the S/D region is coplanar with the top surface of the substrate. The back side metal via is electrically connected to a back surface of the S/D region and to the back side power supply line, where the back surface is opposite to the front surface of the S/D region.

Embodiments of the present disclosure include a method forming a power supply interconnect structure for a memory cell. The method includes forming a transistor structure in a substrate, where the transistor structure includes a source/drain (S/D) region. The method also includes forming a front side interconnect structure above a top surface of the substrate. In forming the front side interconnect structure, a front side metal via in contact with a front surface of the S/D region is formed, where the front surface of the S/D region is coplanar with the top surface of the substrate. A front side metal line in contact with the front side metal via is also formed. The method further includes forming a back side interconnect structure below a bottom surface of the substrate, where the bottom surface is opposite to the top surface of the substrate. In forming the back side interconnect structure, a back side metal via in contact with a back surface of the S/D region is formed, where the back surface is opposite to the front surface of the S/D region. A back side metal line in contact with the back side metal via is also formed.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the scope of the present disclosure, and that they may make various changes, substitutions, and alterations herein without departing from the scope of the present disclosure.

What is claimed is:

1. A semiconductor structure, comprising:
a substrate;
a first transistor structure disposed in the substrate and comprising a first source/drain (S/D) region;
a second transistor structure disposed in the substrate and comprising a second SID region;
a first front side metal via in contact with a front surface of the first S/D region, wherein the front surface of the first S/D region is coplanar with a top surface of the substrate;
a second front side metal via in contact with a front surface of the second S/D region, wherein the front surface of the second S/D region is coplanar with the top surface of the substrate;
a first back side metal via in contact with a back surface of the first S/D region, wherein the back surface of the first S/D region is opposite to the front surface of the first S/D region;
a second back side metal via in contact with a back surface of the second S/D region, wherein the back surface of the second S/D region is opposite to the front surface of the second SID region;
a front side metal line above the top surface of the substrate and in contact with the first and second front side metal vias; and
a back side metal line below a bottom surface of the substrate and in contact with the first back side metal via, wherein the bottom surface is opposite to the top surface of the substrate.

2. The semiconductor structure of claim 1, further comprising an other back side metal line below the bottom surface of the substrate and in contact with the second back side metal via, wherein the other back side metal line is at a same metallization level as the back side metal line below the bottom surface of the substrate.

3. The semiconductor structure of claim 1, further comprising:
a third front side metal via in contact with the front side metal line; and
an other front side metal line in contact with the third front side metal via.

4. The semiconductor structure of claim 3, further comprising:
a fourth front side metal via in contact with the other front side metal line; and
a third front side metal line in contact with the fourth front side metal via, wherein the third front side metal line is electrically connected to a power supply metal line.

5. The semiconductor structure of claim 1, further comprising:
a third transistor structure disposed in the substrate and comprising a third S/D region;
a third front side metal via in contact with a front surface of the third S/D region, wherein the front surface of the third S/D region is coplanar with the top surface of the substrate;
a third back side metal via in contact with a back surface of the third S/D region and in contact with the back side metal line, wherein the back surface of the third S/D region is opposite to the front surface of the third S/D region; and
an other front side metal line above the top surface of the substrate and in contact with the third front side metal via, wherein the other front side metal line is at a same metallization level as the front side metal line above the top surface of the substrate.

6. The semiconductor structure of claim 1, further comprising:
a third transistor structure disposed in the substrate and comprising a third S/D region; and
a third back side metal via in contact with a back surface of the third S/D region and in contact with the back side metal line, wherein the back surface of the third S/D region is opposite to the top surface of the substrate.

7. The semiconductor structure of claim 1, further comprising:
a third back side metal via in contact with the back side metal line; and
an other back side metal line below the back side metal line and in contact with the third back side metal via.

8. The semiconductor structure of claim 1, wherein the first and second back side metal vias are embedded in the substrate, and wherein the first back side metal via is in contact with the back side metal line along a surface of the back side metal line coplanar with the bottom surface of the substrate.

9. A semiconductor structure, comprising:
a transistor structure disposed in a substrate and comprising a source/drain (S/D) region;
a front side power supply line above a top surface of the substrate;
a back side power supply line below a bottom surface of the substrate, wherein the bottom surface is opposite to the top surface of the substrate;
a front side metal via electrically connected to a front surface of the S/D region and to the front side power supply line, wherein the front surface of the S/D region is coplanar with the top surface of the substrate; and
a back side metal via electrically connected to a back surface of the S/D region and to the back side power supply line, wherein the back surface is opposite to the front surface of the S/D region.

10. The semiconductor structure of claim 9, further comprising:
an other transistor disposed in the substrate and comprising an other S/D region;
an other back side power supply line below the bottom surface of the substrate and at a same metallization level as the back side power supply line below; and
an other back side metal via electrically connected to a back surface of the other S/D region and to the other back side power supply line, wherein the back surface of the other S/D region is opposite to the top surface of the substrate.

11. The semiconductor structure of claim 9, further comprising:
an other front side metal via in contact with the front side power supply line; and
an other front side power supply line in contact with the other front side metal via.

12. The semiconductor structure of claim 11, further comprising:
a third front side metal via in contact with the other front side power supply line; and
a third front side power supply line in contact with the third front side metal via, wherein the third front side power supply line is electrically connected to a power supply metal line.

13. The semiconductor structure of claim 9, further comprising:
an other back side metal via in contact with the back side power supply line; and
an other back side power supply line below the back side power supply line and in contact with the other back side metal via.

14. The semiconductor structure of claim 9, wherein the back side metal via is embedded in the substrate, and wherein the back side metal via is in contact with the back side power supply line along a surface of the back side power supply line coplanar with the bottom surface of the substrate.

15. The semiconductor structure of claim 9, wherein the transistor structure is a p-type transistor structure.

16. A method, comprising:
forming a transistor structure in a substrate, wherein the transistor structure comprises a source/drain (S/D) region;
forming a front side interconnect structure above a top surface of the substrate, comprising:
forming a front side metal via in contact with a front surface of the S/D region, wherein the front surface of the S/D region is coplanar with the top surface of the substrate; and
forming a front side metal line in contact with the front side metal via; and
forming a back side interconnect structure below a bottom surface of the substrate, wherein the bottom surface is opposite to the top surface of the substrate, and wherein forming the back side interconnect structure comprises:
forming a back side metal via in contact with a back surface of the S/D region, wherein the back surface is opposite to the front surface of the S/D region; and
forming a back side metal line in contact with the back side metal via.

17. The method of claim 16, further comprising electrically connecting the front side metal line to a power supply metal line.

18. The method of claim 16, further comprising forming an other transistor structure in the substrate, wherein the other transistor comprises an other S/D region.

19. The method of claim 18, wherein forming the front side interconnect structure further comprises forming an other front side metal via in contact with a front surface of the other S/D region and the front side metal line, wherein the front surface of the other S/D region is coplanar with the top surface of the substrate.

20. The method of claim 18, wherein forming the back side interconnect structure further comprises:
forming an other back side metal line below the bottom surface of the substrate; and
forming an other back side metal via in contact with a back surface of the other S/D region and the other back side metal line.
